(19) United States
(12) Patent Application Publication
(10) Pub. No.: US 2014/0184020 A1
(43) Pub. Date: Jul. 3, 2014

(54) ULTRASONIC VIBRATION APPARATUS

(71) Applicant: Olympus Corporation, Tokyo (JP)

(72) Inventors: Tomoki FUNAKUBO, Tokyo (JP); Hiroshi TSURUTA, Kanagawa (JP)

(73) Assignee: OLYMPUS CORPORATION, Tokyo (JP)

(21) Appl. No.: 14/200,657

(22) Filed: Mar. 7, 2014

Related U.S. Application Data
(63) Continuation of application No. PCT/JP2012/075581, filed on Sep. 26, 2012.

(30) Foreign Application Priority Data
Oct. 24, 2011 (JP) 2011-233280

(51) Int. Cl. H01L 41/09

(52) U.S. Cl. CPC H01L 41/0986
USPC 310/317

(57) ABSTRACT

Substantially uniform rigidity is ensured in all radial directions while achieving a size reduction. An ultrasonic surgical apparatus is provided, including a polygonal columnar elastic body that is formed of an elastic body and that has a substantially regular polygonal cross-section; plate-like piezoelectric elements that are secured to mutually opposing side surfaces of the polygonal columnar elastic body and that are polarized in a plate-thickness direction; a rod-like contactor that is secured to an end of the polygonal columnar elastic body and that has a smaller diameter than the polygonal-columnar elastic body; and a drive-pulse generating circuit that causes the rod-like contactor to ultrasonically vibrate by generating a vertical vibration which expands/contracts the polygonal columnar elastic body in the longitudinal direction by applying an AC voltage to the piezoelectric elements in the plate-thickness direction.

### CROSS REFERENCE TO RELATED APPLICATIONS

This is a continuation of International Application PCT/JP2012/075581, with an international filing date of Sep. 26, 2012, which is hereby incorporated by reference herein in its entirety. This application claims the benefit of Japanese Patent Application No. 2011-233280, the contents of which are incorporated herein by reference.

### TECHNICAL FIELD

The present invention relates to an ultrasonic vibration apparatus.

### BACKGROUND ART

In the related art, there are known devices for removing fat, examples of which are ultrasonic vibration apparatuses disclosed in Patent Literatures 1 and 2. The ultrasonic vibration apparatus disclosed in Patent Literature 1 is provided with a bolt-clamped Langevin transducer serving as a transducer. In addition, an ultrasonic surgical instrument disclosed in Patent Literature 2 is provided with a plurality of transducers, laminated together, in which piezoelectric elements are attached on only one side surface of a plate-like elastic body that includes a terminal effector such as a cutting/coagulating blade.

### CITATION LIST

### Patent Literature

{PTL 1} Japanese Examined Patent Application, Publication No. Hei 6-20462
{PTL 2} Japanese Unexamined Patent Application, Publication No. 2009-136700

### SUMMARY OF INVENTION

### Solution to Problem

An aspect of the present invention is an ultrasonic vibration apparatus including a columnar member that is formed of an elastic body and that has a substantially circular cross-section or a substantially regular polygonal cross-section; plate-like piezoelectric elements that are secured on mutually opposing side surfaces of the columnar member and that are polarized in a plate-thickness direction; a rod-like member that is secured to an end of the columnar member and that has a smaller diameter than the columnar member; and a voltage applying portion that causes the rod-like member to ultrasonically vibrate by generating a vertical vibration which expands/contracts the columnar member in the longitudinal direction by applying an AC voltage to the piezoelectric elements in the plate-thickness direction.

### BRIEF DESCRIPTION OF DRAWINGS

FIG. 1 is an overall configuration diagram of an ultrasonic surgical apparatus according to a first embodiment of the present invention.

FIG. 2 is a top view of a transducer in FIG. 1.

FIG. 3 is a side view of the transducer in FIG. 1.

FIG. 4 is an external view of a piezoelectric element in FIGS. 2 and 3.

FIG. 5 is a top view of a relevant portion of the ultrasonic surgical apparatus in FIG. 1.

FIG. 6 is a sectional view taken along A-A′ in FIG. 5.

FIG. 7 is a diagram showing a stretching vibration in the axial direction when operating the transducer in FIG. 1.

FIG. 8 is a diagram for explaining the operational effect of the ultrasonic surgical apparatus in FIG. 1.

FIG. 9 is a diagram for explaining another operational effect of the ultrasonic surgical apparatus in FIG. 1.

FIG. 10 is a top view of a transducer according to a first modification.

FIG. 11 is a side view of the transducer in FIG. 10.

FIG. 12 is a top view of a transducer according to a second modification.

FIG. 13 is a top view of another transducer according to the second modification.

FIG. 14 is a top view of a transducer according to a third modification.

FIG. 15 is a side view of the transducer in FIG. 14.

FIG. 16 is a top view of a transducer according to a fourth modification.

FIG. 17 is a side view of the transducer in FIG. 16.

FIG. 18 is a top view of a transducer according to a fifth modification.

FIG. 19 is a side view of the transducer in FIG. 18.

FIG. 20 is a top view of another transducer according to the fifth modification.

FIG. 21 is a side view of the transducer in FIG. 20.

FIG. 22 is a top view of a transducer according to a sixth modification.

FIG. 23 is a top view of a transducer according to a second embodiment of the present invention.

FIG. 24 is a side view of the transducer in FIG. 23.

FIG. 25 is a longitudinal sectional view of a relevant portion of the ultrasonic surgical apparatus according to the second embodiment of the present invention.

FIG. 26 is a top view of a transducer according to a seventh modification.

FIG. 27 is a side view of the transducer in FIG. 26.

FIG. 28 is a partially enlarged longitudinal sectional view of a rod-like contactor in FIG. 27.

FIG. 29 is an external view of a piezoelectric element according to a third embodiment of the present invention.

FIG. 30 is an overall configuration diagram of an ultrasonic surgical apparatus according to the third embodiment of the present invention.

FIG. 31 is a flowchart showing processing executed by the ultrasonic surgical apparatus in FIG. 30.

FIG. 32 is a graph for explaining the operational effect of the ultrasonic surgical apparatus in FIG. 30.

FIG. 33 is an external view of a piezoelectric element according to a fourth embodiment of the present invention.

FIG. 34 is an exploded view of the piezoelectric element in FIG. 33.

FIG. 35 is a sectional view of the piezoelectric element in FIG. 33, taken along A-A′.

### DESCRIPTION OF EMBODIMENTS

### First Embodiment

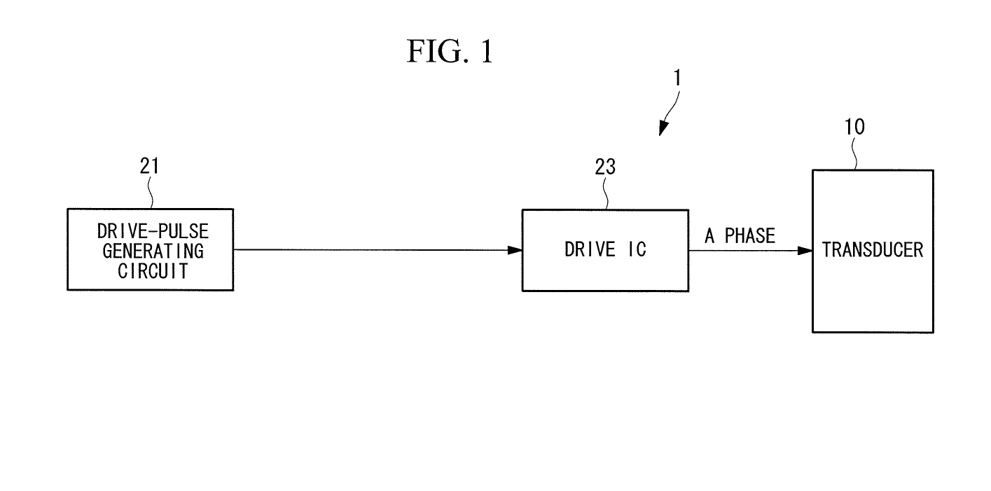

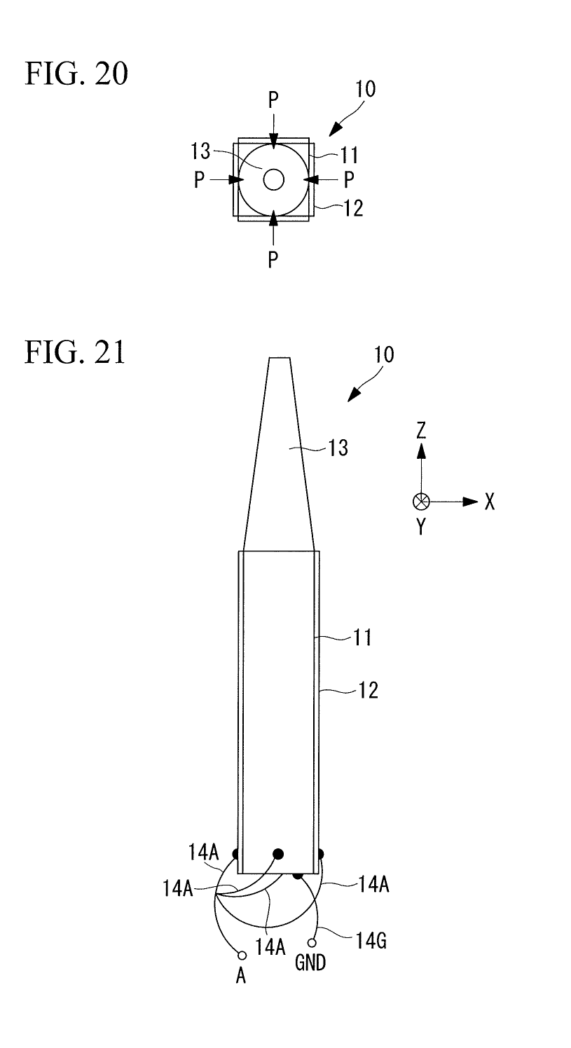

A first embodiment of the present invention will be described below by using FIGS. 1 to 22. Hereinafter, an example in which an ultrasonic vibration apparatus according to the present invention is employed in an ultrasonic surgical apparatus for removing fat in a body cavity will be described.

As shown in FIG. 1, an ultrasonic surgical apparatus 1 according to this embodiment is provided with a transducer 10 that is inserted into a body cavity, a drive-pulse generating circuit (voltage applying portion) 21 that generates drive pulses, and a drive IC 23 that amplifies the drive pulses and outputs them to the transducer 10.

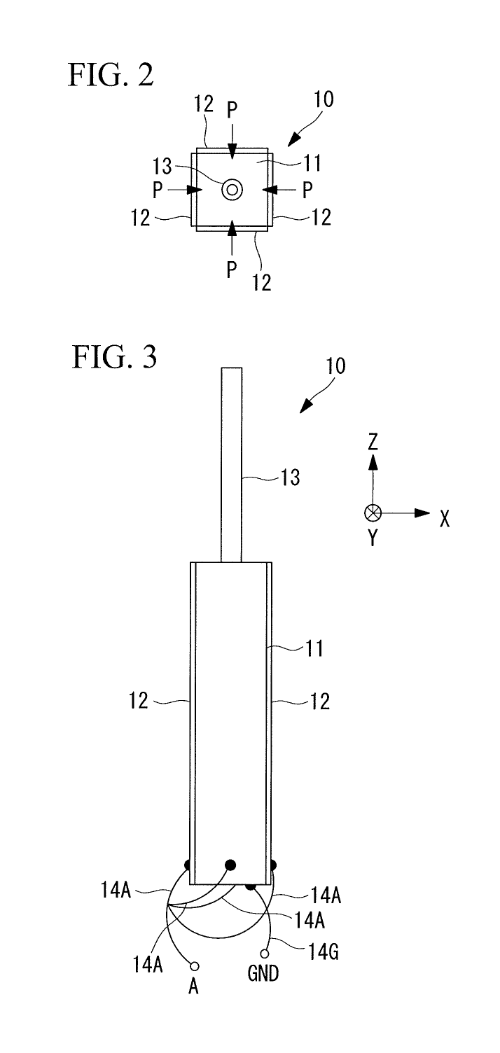

As shown in FIGS. 2 and 3, the transducer 10 is provided with a columnar member (polygonal column member, hereinafter, referred to as the polygonal columnar elastic body) 11 that is a rectangular column formed of an elastic body, plate-like piezoelectric elements 12 that are secured to the four side surfaces of the polygonal columnar elastic body 11, each of which is polarized in the plate-thickness direction, and a rod-like contactor (rod-like member) 13 that is secured to an end of the polygonal columnar elastic body 11 and that has a smaller diameter than the polygonal columnar elastic body 11.

The material for the polygonal columnar elastic body 11 is formed of a component having a large Q value, such as a titanium alloy, stainless steel, and so forth. The piezoelectric elements 12 are bonded to the four side surfaces of the polygonal columnar elastic body 11 by using epoxy resin. A hole is provided at the top end of the polygonal columnar elastic body 11, into which the rod-like contactor 13 is inserted and secured by means of press fitting or bonding.

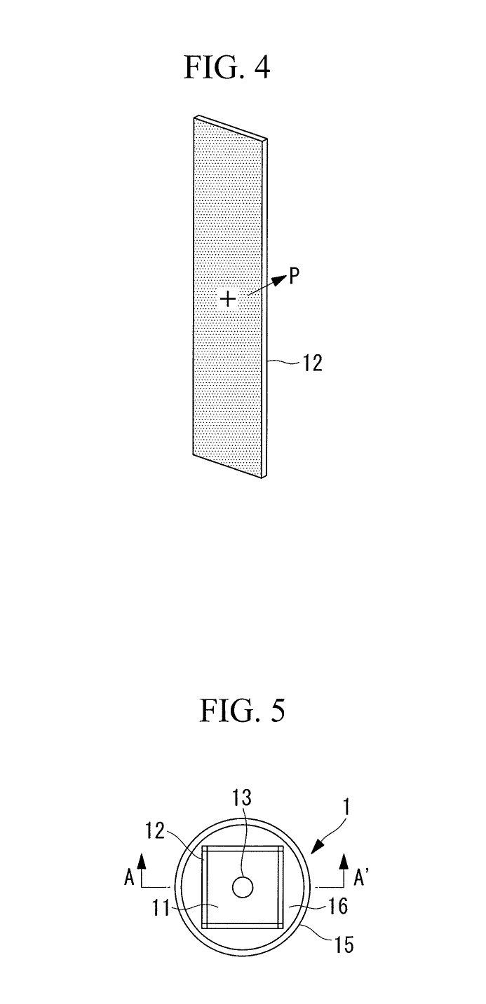

The raw material for the piezoelectric elements 12 is lead zirconate titanate (PZT). As shown in FIG. 4, the piezoelectric elements 12 have a rectangular plate shape provided with electrodes on the front surface and the back surface thereof and are polarized in the plate-thickness direction. As shown in FIG. 4, the polarization direction is shown by a polarization vector P, and the polarization vector P is a vector directed toward the negative surface (back surface) from the positive surface (front surface). These piezoelectric elements 12 are attached on the four side surfaces, paying attention to the polarization direction, so that the direction of each polarization vector P points to the polygonal columnar elastic body 11, as shown in FIG. 2.

As shown in FIG. 3, leads 14A for applying an AC voltage to the piezoelectric elements 12 are connected to the electrode surfaces of the piezoelectric elements 12 by means of conductive adhesive or soldering. These four leads 14A are connected to each other, forming an A terminal that serves as a drive phase. A GND terminal that serves as a shared electrode is formed by a lead 14G that is connected to the bottom surface of the polygonal columnar elastic body 11 by means of conductive adhesive or soldering.

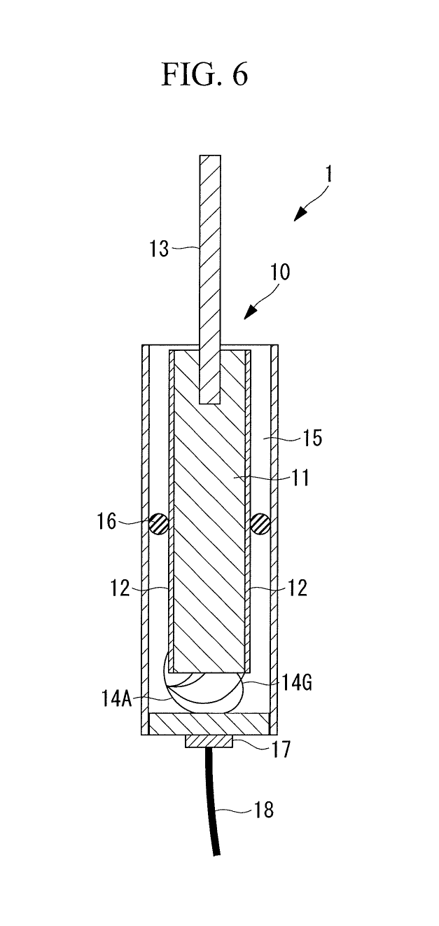

As shown in FIGS. 5 and 6, case 15 having a circular shape is provided outside of the transducer 10 so as to enclose the transducer 10. The transducer 10 enclosed in the case 15 forms a main portion of the ultrasonic surgical apparatus 1. A rubber piece (holding member) 16 is provided between the transducer 10 and the case 15 near a node of a vertical vibration that occurs in the transducer 10, described later. In other words, the transducer 10 is held in the case 15 by means of the rubber piece 16. By holding the transducer 10 near the node, it is possible to prevent the vibrational energy from escaping outside the case 15 and so forth.

In addition, a connector 17 for the leads 14A and 14G is provided at the bottom surface of the case 15. A holding wire 18 is connected to the connector 17. Although not shown in the figures, the leads 14A and 14G are contained inside the holding wire 18. In addition, the holding wire 18 concurrently plays a role in holding and manipulating the case 15 (and the transducer 10 in the interior thereof).

As shown in FIG. 1, the drive-pulse generating circuit 21 outputs drive pulses of a frequency that corresponds to a predetermined resonance frequency. By doing so, the drive-pulse generating circuit 21 generates a vertical vibration in the polygonal columnar elastic body 11 by applying an AC voltage to the piezoelectric elements 12 in the plate-thickness direction via the leads 14A, thus generating an ultrasonic vibration in the rod-like contactor 13. The details of the operation involved when generating the vertical vibration in the polygonal columnar elastic body 11 will be described later.

The drive IC 23 amplifies the drive pulses from the drive-pulse generating circuit 21 and outputs them to the transducer 10.

As described above, by applying each drive pulse amplified by the drive IC 23 to the A phase of the transducer 10, it is possible to cause the transducer 10 (rod-like contactor 13) to expand/contract in an axial direction.

The operational effect of the ultrasonic surgical apparatus 1 according to this embodiment having the above-described configuration will be described below.

First, the operation of the transducer 10 will be described.

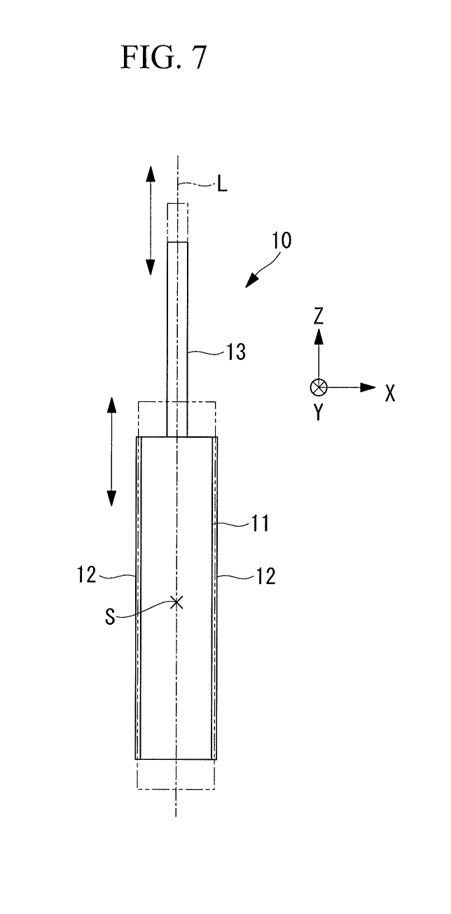

When an AC voltage is applied between the A terminal and the GND terminal, forces that cause expansion/contraction are generated in the four piezoelectric elements 12 in a direction orthogonal to the polarization direction, that is, a direction orthogonal to the plate-thickness direction, and all of the piezoelectric elements 12 simultaneously expand or simultaneously contract. Therefore, by applying an AC voltage having the resonance frequency for the vertical vibration (vibration in a direction parallel to an axial line L) of the polygonal columnar elastic body 11, a vertical vibrational mode can be excited in the polygonal columnar elastic body 11 by the expansion/contraction of the four piezoelectric elements 12, as shown in FIG. 7.

Although vertical vibrational modes of lower orders as well as those of higher orders exist, a vertical vibrational mode in which a node S exists at one location in substantially the center portion of the polygonal columnar elastic body 11 is excited, as shown in FIG. 7. As a result, a vibration in the direction parallel to the axial line L is transmitted to the rod-like contactor 13 by the vertical vibration of the polygonal columnar elastic body 11, which causes the rod-like contactor 13 to ultrasonically vibrate (vertically vibrate) in the direction of the axial line L.

Control of the drive circuit in this case will be described below.

As shown in FIG. 1, drive pulses having a frequency corresponding to a predetermined resonance frequency are output from the drive-pulse generating circuit 21 and is amplified by the drive IC 23. The signal amplified by the drive IC 23 is applied to the A phase, causing the transducer 10 (rod-like contactor 13) to expand/contract in the direction of the axial line L.

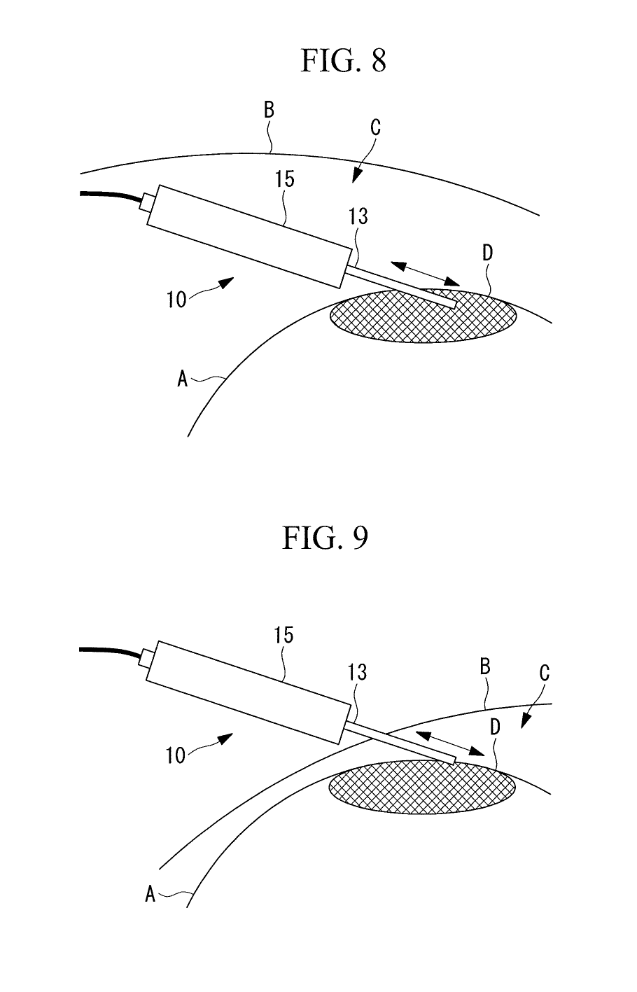

The operational effect of the ultrasonic surgical apparatus 1 provided with the transducer 10 that performs the above-described operation will be described by using FIGS. 8 and 9.

In FIG. 8, the transducer 10 is inserted into a pericardial cavity C, which is a space between a pericardium B and an epicardium (a membrane at an outer surface of the heart) A via a sheath or the like. In general, myocardial infarction or the like is caused by fat D adhered to a cardiac-muscle surface. By coming into contact with the fat D at the tip thereof, the vertically vibrating rod-like contactor 13 can cause the fat D to melt (emulsify) by means of ultrasonic vibrations. Note that, as shown in FIG. 9, the fat removal may be performed by inserting only the rod-like contactor 13 into the pericardial cavity C.

As described above, with the ultrasonic surgical apparatus 1 according to this embodiment, by generating vertical vibrations in the polygonal columnar elastic body 11 by causing all of the four piezoelectric elements 12 to simultaneously expand/contract in the direction orthogonal to the plate-thickness direction thereof, vertical vibrations are transmitted to the rod-like contactor 13, and the rod-like contactor 13 is ultrasonically vibrated in the direction of the axial line L. Therefore, by inserting such an ultrasonically vibrating rod-like contactor 13 into a body cavity, such as a pericardial cavity or the like, and by bringing the tip thereof into contact with fat adhered to an internal wall of the body cavity, the fat can be melted (emulsified) by friction between the tip of the rod-like contactor 13 and the fat.

In this case, by constructing the transducer 10 by securing the plate-like piezoelectric elements 12 on the four side surfaces of the polygonal columnar elastic body 11 having a substantially regular polygonal cross-section, it is possible to ensure substantially uniform rigidity in all radial directions of the transducer 10 while achieving a reduction in the diameter of the polygonal columnar elastic body 11, as well as a size reduction in the piezoelectric elements 12. Accordingly, for example, regardless of the angle and orientation with which the tip of the rod-like contactor 13 is brought into contact with fat, the fat can be melted by uniformly generating friction. In addition, by reducing the diameter of the transducer 10, fat adhered to a cardiac-muscle surface can easily be melted inside the pericardial cavity or from outside the pericardial cavity.

### First Modification

A first modification of the ultrasonic surgical apparatus 1 according to this embodiment will be described below.

Note that, hereinafter, for ultrasonic surgical apparatuses according to individual modifications, the same reference signs will be assigned to commonalties with the embodiment described above, omitting descriptions thereof, and differences will mainly be described.

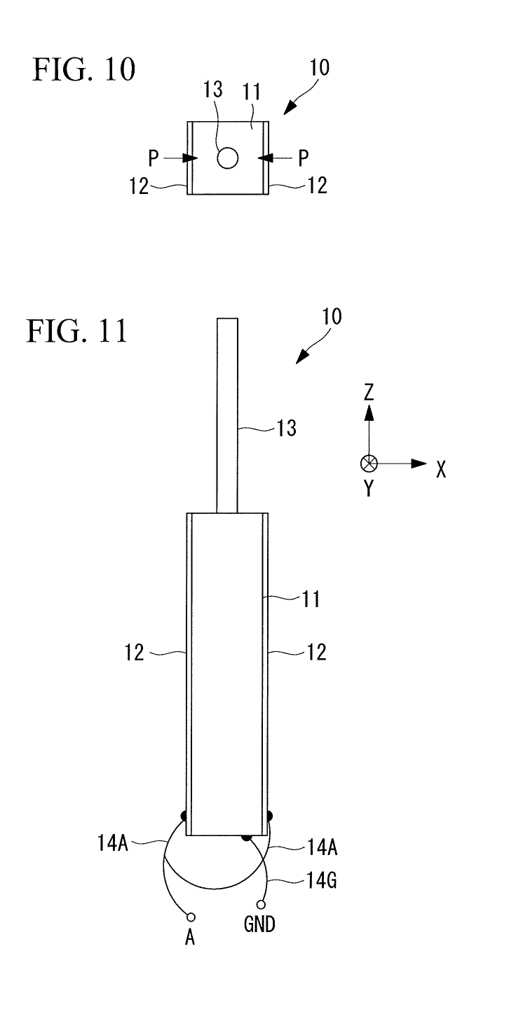

Although the piezoelectric elements 12 are bonded to the four side surfaces of the polygonal columnar elastic body 11 in the above-described embodiment, as the first modification, a pair of the piezoelectric elements 12 may be attached on only two mutually opposing side surfaces of the polygonal columnar elastic body 11, as shown in FIGS. 10 and 11. By doing so, it is possible to achieve further size reduction of the transducer 10. In addition, when such a modification is employed, efficient fat removal is also possible by generating highly symmetrical vertical vibrations in the polygonal columnar elastic body 11 and the rod-like contactor 13.

### Second Modification

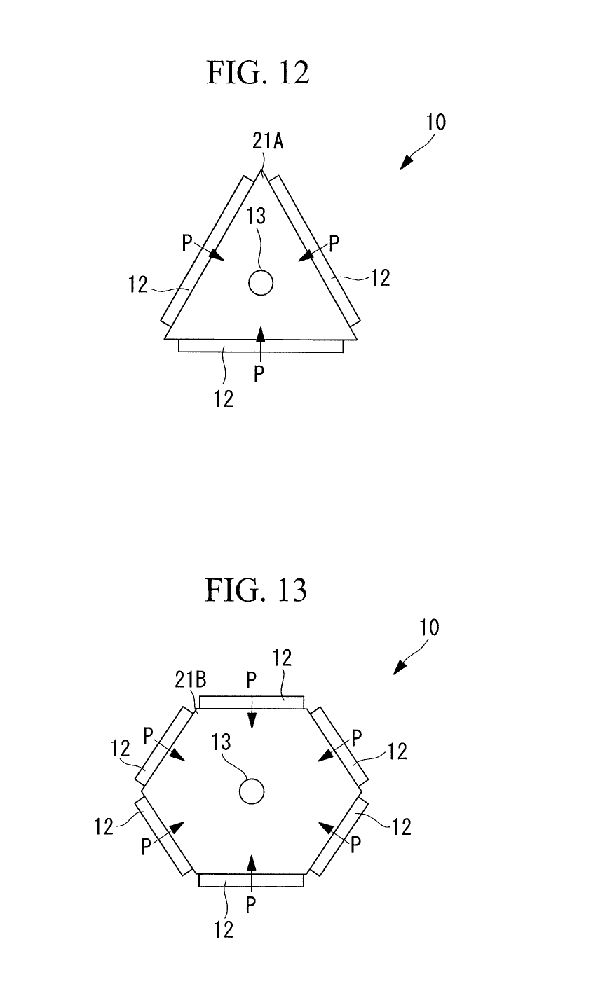

Although the polygonal columnar elastic body 11 that is a quadrangular column has been described in this embodiment as an example of the columnar member, it suffices to have a substantially polygonal columnar member, and there is no limitation to the number of angles n (n is any integer). As a second modification, for example, a polygonal columnar member 21A that is a triangular columnar the one shown in FIG. 12 or a polygonal columnar member 21B that is a hexagonal columnar the one shown in FIG. 13 may be employed, and the piezoelectric elements 12 may be secured to individual side surfaces thereof. When such a modification is employed, it is also possible to generate highly symmetrical vertical vibrations in the polygonal columnar elastic body 21A or 21B and the rod-like contactor 13.

### Third Modification

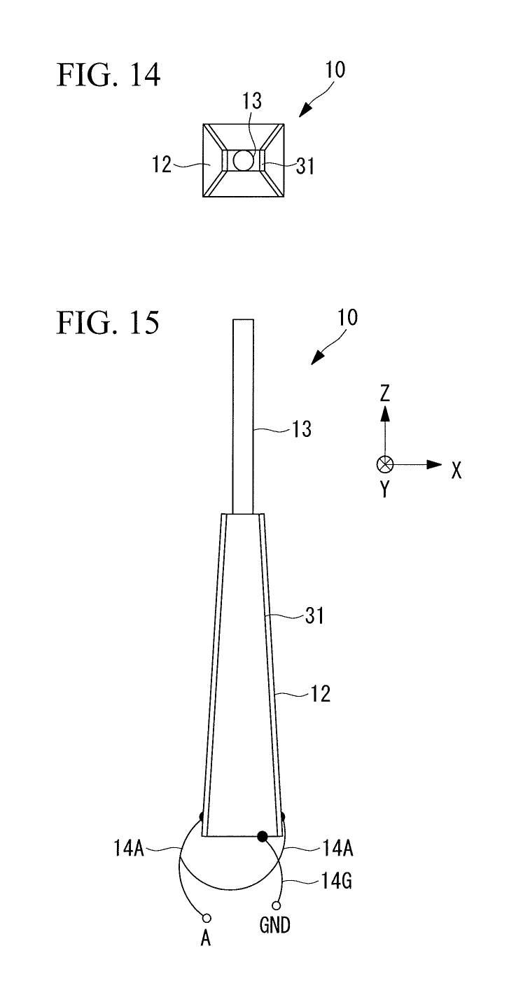

Although the polygonal columnar elastic body 11 is employed as an elastic body (columnar member) in the above-described embodiment, as a third modification, a geometrical pyramid-like elastic body 31 in which the lateral cross-sectional area decreases toward the tip thereof may be employed, as shown in FIGS. 14 and 15. In this case, piezoelectric elements 12 having a trapezoidal planar shape are employed.

With an ultrasonic surgical apparatus according to this modification, it is possible to make the mechanical impedances of the rod-like contactor 13 and the geometrical pyramid-like elastic body 31 similar at the vicinity of a connecting position between the rod-like contactor 13 and the geometrical pyramid-like elastic body 31. Therefore, good mechanical impedance matching can be achieved, and the vibrational energy of the geometrical pyramid-like elastic body 31 can be transmitted to the rod-like contactor 13 more efficiently.

In addition, by employing the geometrical pyramid-like elastic body 31, the lateral cross-sectional area of the geometrical pyramid-like elastic body 31 can be increased at the basal end thereof. Accordingly, large surface areas can be ensured for the piezoelectric elements 12 joined with the side surfaces of the geometrical pyramid-like elastic body 31, which makes it possible to increase the vibrational energy generated in the geometrical pyramid-like elastic body 31. In addition, it is possible to make the tip of the transducer 10 smaller, and the usability of the apparatus can be improved by enhancing the ease of insertion into a body cavity and so forth.

### Fourth Modification

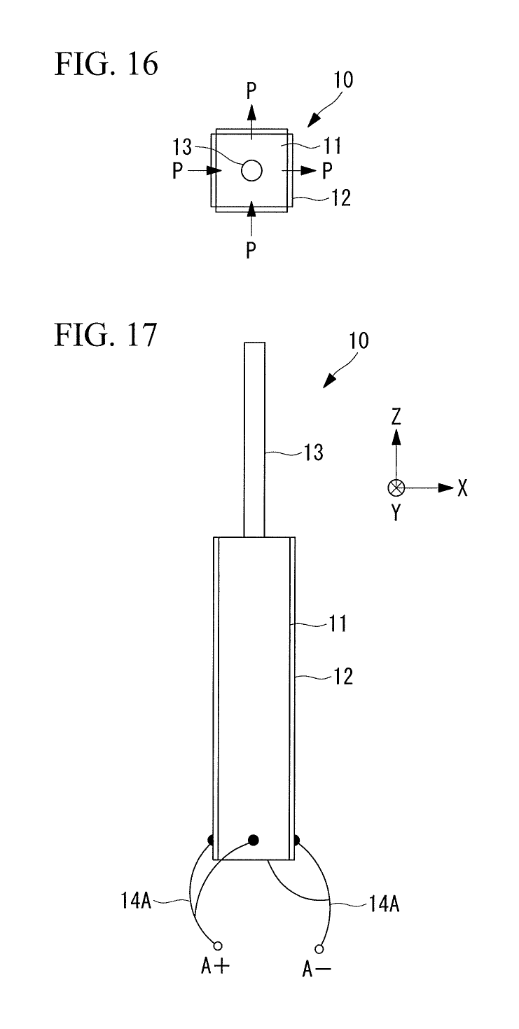

Although the individual piezoelectric elements 12 in the above-described embodiment are secured so that the orientation of polarization (orientation of the polarization vector P) is toward the polygonal columnar elastic body 11 for all of the piezoelectric elements 12, as a fourth modification, the piezoelectric elements 12 are secured to the four side surfaces of the polygonal columnar elastic body 11 so that the polarization vectors P of the mutually opposing piezoelectric elements 12 are in the same direction, as shown in FIGS. 16 and 17.

In addition, with regard to the leads 14, the shared GND terminal is eliminated, one side in each pair of mutually opposing piezoelectric elements 12 serves as a positive A terminal, and the other side serves as a negative A terminal in driving the apparatus. By doing so, because all of the piezoelectric elements 12 expand/contract with the same phase as each other, vertical vibrations can be excited in the polygonal columnar elastic body 11. In addition, it is possible to reduce the number of the leads 14 by an amount corresponding to number of the GND terminal.

### Fifth Modification

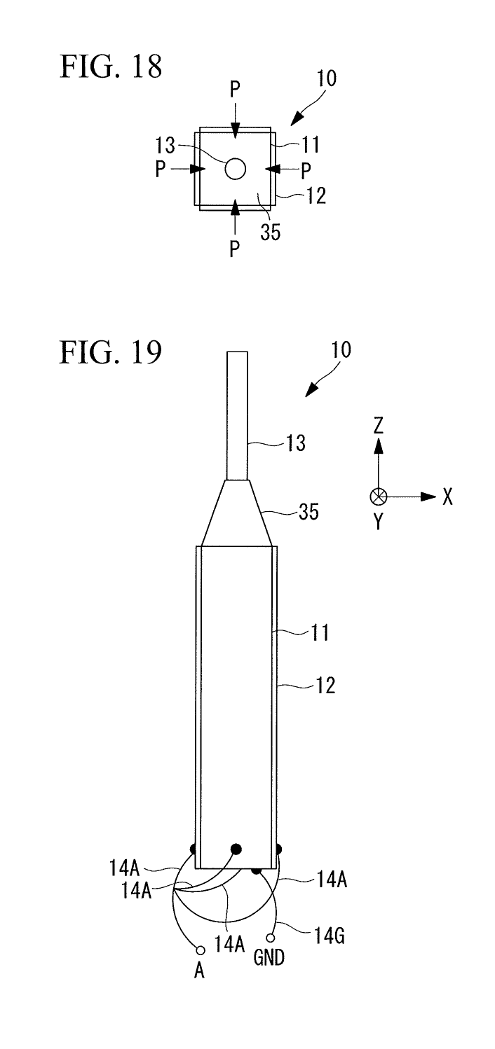

Although the rod-like contactor 13 in the above-described embodiment is inserted into and secured at the hole of the polygonal columnar elastic body 11 by means of press fitting or bonding, as a fifth modification, a circular cone-shaped horn member 35, in which the lateral cross-sectional area thereof gradually decreases toward the rod-like contactor 13 from the polygonal columnar elastic body 11, is provided between the polygonal columnar elastic body 11 and the rod-like contactor 13, as shown in FIGS. 18 and 19.

By inserting such a horn member 35, mechanical impedances can be matched between the polygonal columnar elastic body 11 and the rod-like contactor 13, and the amplitude of the rod-like contactor 13 can be increased.

Although this modification has been described in terms of an example in which the horn member 35 has a circular-cone shape, alternatively, a horn member having a geometrical-pyramid shape may be employed.

In addition, although the horn member 35 is provided in this modification, alternatively, the shape of the rod-like contactor 13 itself may be formed in a horn shape of a circular-cone type (or geometrical-pyramid type). When employing such a modification, because the cross-sectional area of the rod-like contactor 13 gradually decreases toward the tip thereof, mechanical impedances can be matched between the polygonal columnar elastic body 11 and the rod-like contactor 13, and the amplitude at the tip of the rod-like contactor 13 can be increased.

### Sixth Modification

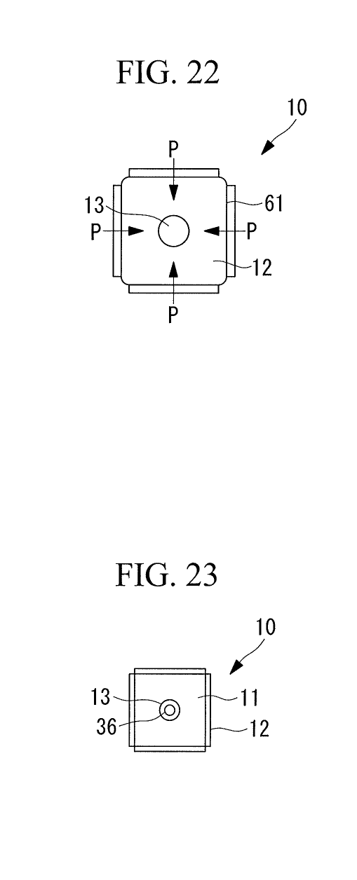

Although the above-described embodiment has been described in terms of an example in which the polygonal columnar elastic body 11 is employed as a columnar member, as a sixth modification, a rounded polygonal columnar elastic body (substantially polygonal columnar member) 61 in which corners of the polygonal columnar elastic body 11 are removed may be employed, as shown in FIG. 22. By doing so, the number of sharp portions is reduced in the polygonal columnar elastic body 61, which facilitates handling thereof.

### Second Embodiment

Next, an ultrasonic surgical apparatus 2 according to a second embodiment of the present invention will be described with reference to FIGS. 23 to 28. Hereinafter, for ultrasonic surgical apparatuses according to individual embodiments, the same reference signs will be assigned to commonalties with the embodiment described above, omitting descriptions thereof, and differences will mainly be described.

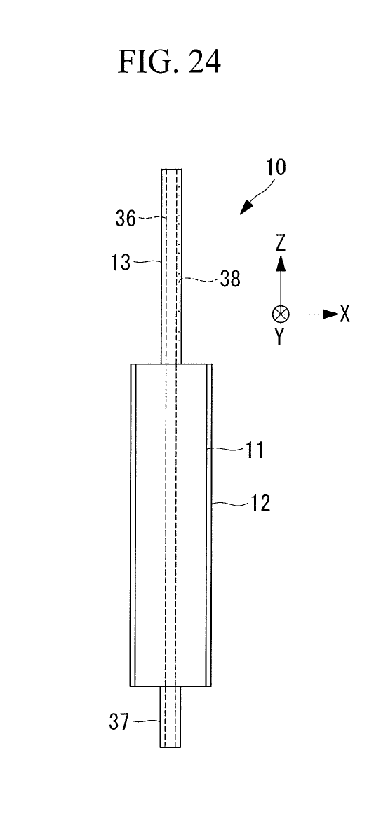

As shown in FIGS. 23 and 24, a rear-end protrusion 37 that protrudes in the axial direction is provided at the bottom end of the polygonal columnar elastic body 11. In addition, the rod-like contactor 13, the polygonal columnar elastic body 11, and the rear-end protrusion 37 are provided with a through-hole (suction path) 36 that passes through them in the axial direction thereof without interruption. Furthermore, a plurality of side holes 38 that communicate with the through-hole 36 are provided in a side surface of the rod-like contactor 13.

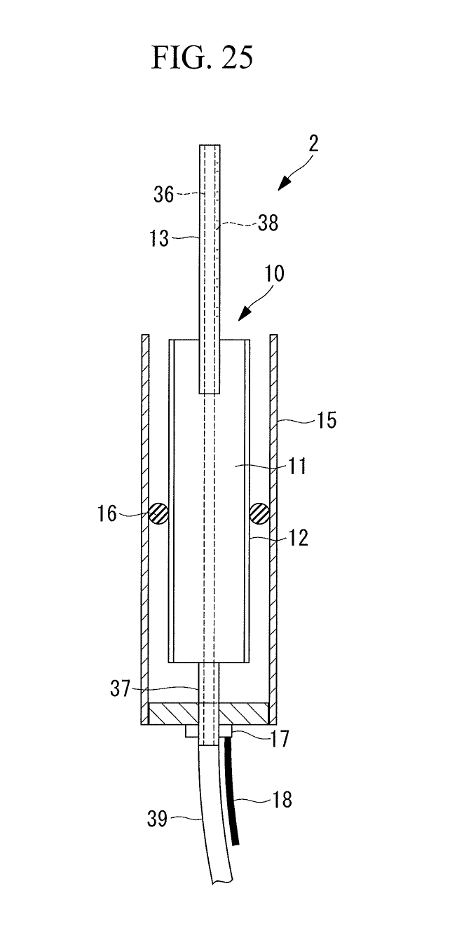

As shown in FIG. 25, the rear-end protrusion 37 is connected to a suction hose 39 by means of the connector 17, and the through-hole 36 communicates with the suction hose 39. The suction hose 39 and the holding wire 18 are extended in a bundled state. Note that, although not illustrated, a suction pump is provided at the other end of the suction hose 39.

Next, the operation of the ultrasonic surgical apparatus 2 according to this embodiment will be described below.

First, as with the above-described embodiment, the transducer 10 of the ultrasonic surgical apparatus 2 according to this embodiment is inserted into the pericardial cavity C via a sheath or the like (see FIG. 8). In this state, a vertical vibration is generated in the polygonal columnar elastic body 11 by applying an AC voltage to the piezoelectric elements 12 in the plate-thickness direction by means of the drive-pulse generating circuit 21, thus generating an ultrasonic vibration in the rod-like contactor 13.

When brought into contact with the fat D at the tip thereof, the ultrasonically vibrating rod-like contactor 13 can cause the fat D to be emulsified. The fat D emulsified by the rod-like contactor 13 is sucked from the through-hole 36 provided in the tip surface of the rod-like contactor 13 or the side holes 38 provided in the side surface thereof, by means of the suction hose 39, and is ejected outside.

As described above, with the ultrasonic surgical apparatus 2 according to this embodiment, in addition to the same advantages afforded by the above-described embodiment, it is possible to eject fat components emulsified by the ultrasonic vibrations of the rod-like contactor 13 outside the body. The through-hole 36 may be used as a liquid-supplying hole when used at different timing from when used as the suction path. Note that, although the side holes 38 in this embodiment are provided only in the X-direction for the sake of illustration, they may be provided in the Y-direction, and it is desirable that the side holes 38 be provided in multiple directions in a radiating manner.

### Seventh Modification

This embodiment can be modified as follows.

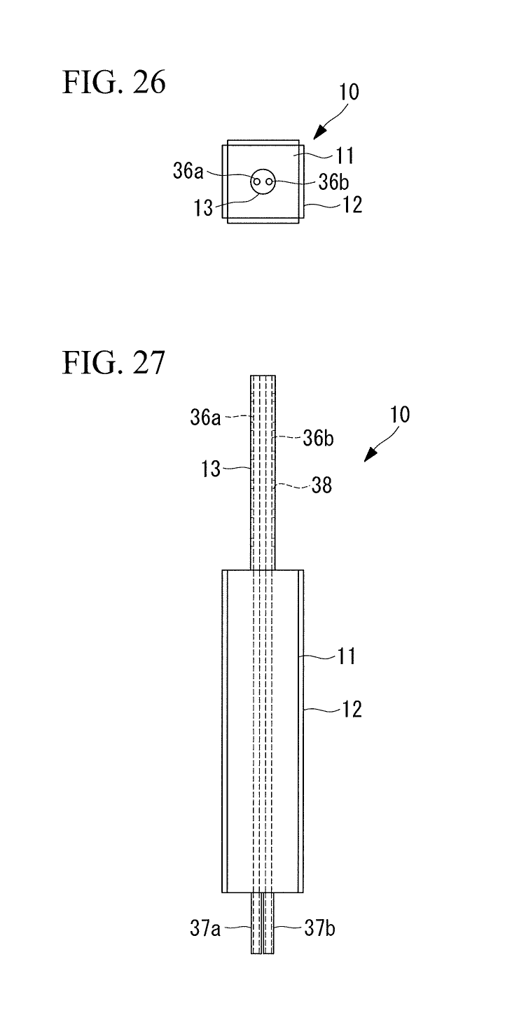

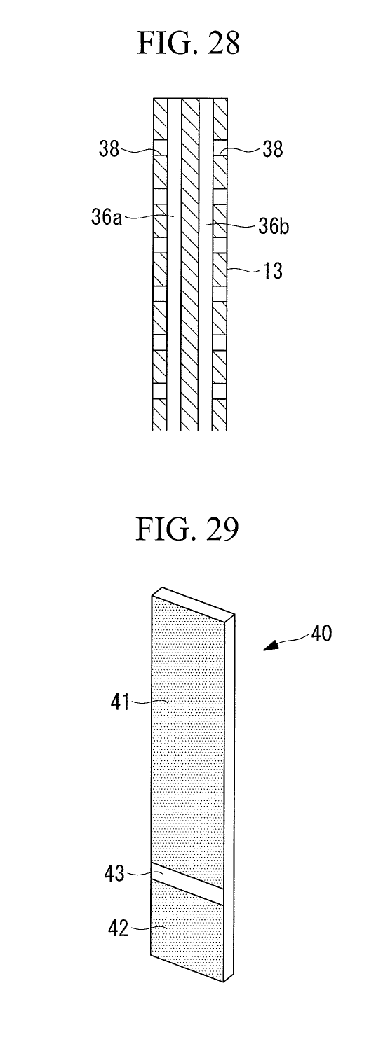

Although one through-hole 36 that communicates through the rod-like contactor 13, the polygonal columnar elastic body 11, and rear-end protrusion 37 is provided in the above-described embodiment, as a seventh modification, a liquid-supplying through-hole (liquid-supplying path) 36a and a suction through-hole (suction path) 36b are provided as independent through-holes, as shown in FIGS. 26 and 27. A rear-end liquid-supplying protrusion 37a and a rear-end suction protrusion 37b, each of which protrudes in the axial direction, are provided at the bottom-end surface of the polygonal columnar elastic body 11. Furthermore, as shown in FIG. 28, the side holes 38 that individually communicate with the liquid-supplying through-hole 36a and the suction through-hole 36b are provided in the side surface of the rod-like contactor 13.

With the ultrasonic surgical apparatus according to this modification, liquid, such as saline solution or the like, can be supplied into the body cavity via the liquid-supplying through-hole 36a, and the liquid (saline solution or the like) can reliably be interposed between a fat portion and the rod-like contactor 13. By doing so, it is possible to facilitate propagation of ultrasonic vibrations to the fat, which makes it possible to enhance the efficiency in emulsifying fat. Although the side holes 38 are provided only in the X-direction in this modification for the sake of illustration, they may be provided in the Y-direction, and it is desirable that the side holes 38 be provided in multiple directions in a radiating manner.

### Third Embodiment

Next, an ultrasonic surgical apparatus 3 according to a third embodiment of the present invention will be described with reference to FIGS. 29 to 32.

As shown in FIG. 29, a feature of a piezoelectric element 40 of the ultrasonic surgical apparatus according to this embodiment is that an electrode thereof is divided into two by an insulating region 43. The upper portion serves as a drive electrode 41 and the lower portion serves as a vibration-detection electrode (vibration-detecting electrode) 42. It suffices that this piezoelectric element 40 be provided at one or more locations among the piezoelectric elements 12 attached on the four side surfaces of the polygonal columnar elastic body 11. Note that, in the case in which the piezoelectric elements 40 are provided at multiple locations, the outputs therefrom should be connected in parallel.

Next, the operation of the ultrasonic surgical apparatus 3 according to this embodiment will be described below.

Although the piezoelectric element 40 is deformed when a voltage is applied thereto (inverse piezoelectric effect), the deformation generates a voltage (piezoelectric effect). Therefore, by observing the voltage of the vibration-detection electrode 42, it is possible to detect an AC voltage proportional to the magnitude of the vibration.

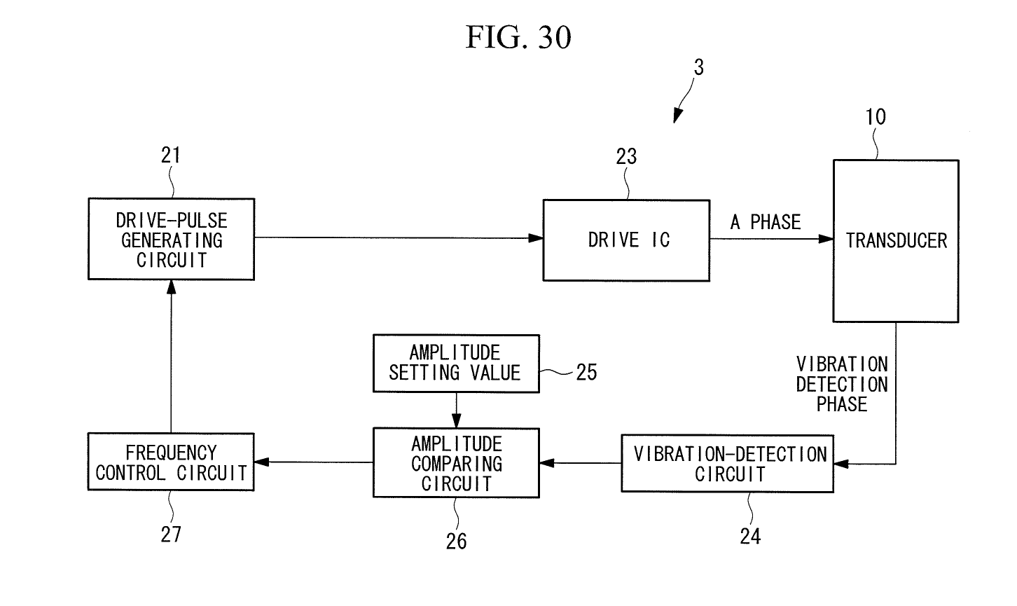

FIG. 30 shows a drive circuit employing the vibration-detection electrode 42 (vibration detection phase).

An AC drive pulses with an initial-value frequency are output from the drive-pulse generating circuit 21 and are amplified by the drive IC 23. The amplified drive pulses are applied to the A phase of the transducer 10.

When the transducer 10 is vibrated, an AC voltage is output from the vibration detection phase. The signal thereof is detected by the vibration-detection circuit 24, is amplified by a predetermined gain, and is input to an amplitude comparing circuit 26. An amplitude value from the vibration output circuit 24 and an amplitude value set in advance as an amplitude setting value 25 are compared at the amplitude comparing circuit 26, and a judgment signal thereof is output to a frequency control circuit (frequency control portion) 27. Here, the frequency to be set is determined, the result of which is output to the drive-pulse generating circuit 21, and the drive frequency is updated. Consequently, the drive pulses generated at the drive-pulse generating circuit 21 are always controlled to a desirable vibration amplitude value.

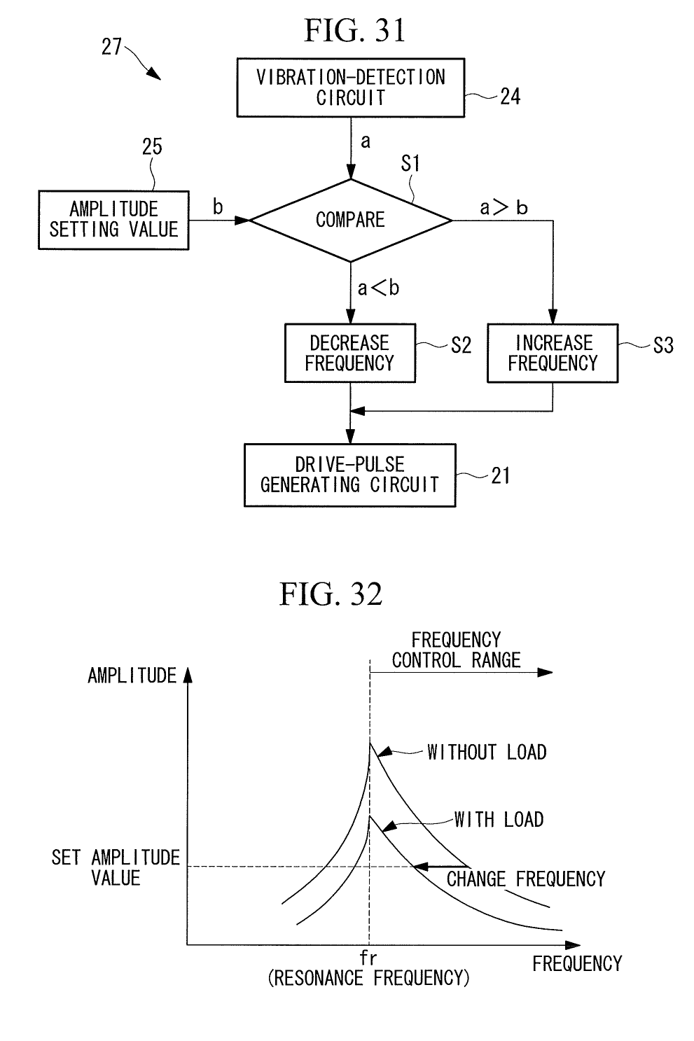

The above-described control will be described below by using the flowchart in FIG. 31.

As shown in FIG. 30, defining the amplitude value of the drive pulses detected by the vibration-detection circuit 24 (hereinafter, referred to as “detected amplitude value”) as a and the amplitude value set in advance as the amplitude setting value 25 (hereinafter, referred to as “set amplitude value”) as b, the detected amplitude value a and the set amplitude value b are compared at the amplitude comparing circuit 26 (Step S1).

If the set amplitude value b is larger than the detected amplitude value a, the drive frequency of the drive pulses generated by the drive-pulse generating circuit 21 is decreased by means of the frequency control circuit 27 (Step S2). On the other hand, if the set amplitude value b is smaller than the detected amplitude value a, the drive frequency of the drive pulses generated by the drive-pulse generating circuit 21 is increased by means of the frequency control circuit 27 (Step S3).

Here, as shown in FIG. 32, the vibration amplitudes of the rod-like contactor 13 and the polygonal columnar elastic body 11 reach maximum values at a resonance frequency (fr). When a load is exerted on the rod-like contactor 13, the amplitude characteristic thereof is reduced overall. Therefore, in that case, the drive frequency is made closer to the resonance frequency so as to achieve the same amplitude. Note that, the frequency control range is set higher than the resonance frequency.

As described above, with the ultrasonic surgical apparatus 3 according to this embodiment, the vibration-detection electrode 42 is provided as an electrode of the piezoelectric element 40; the vibration of the transducer 10 is constantly detected; and the frequency is constantly controlled so that the detected value is kept constant. By doing so, the amplitude value of the polygonal columnar elastic body 11, that is, the amplitude value of the ultrasonic vibration in the rod-like contactor 13, can be maintained constant, even when load fluctuation occurs in the vibration amplitude, which makes it possible to achieve stable melting of fat.

### Fourth Embodiment

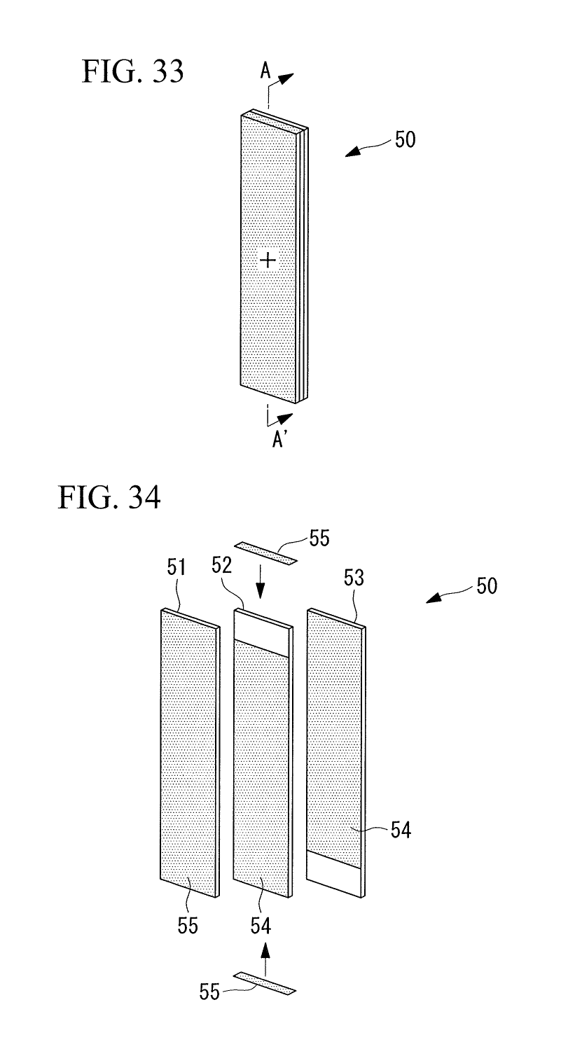

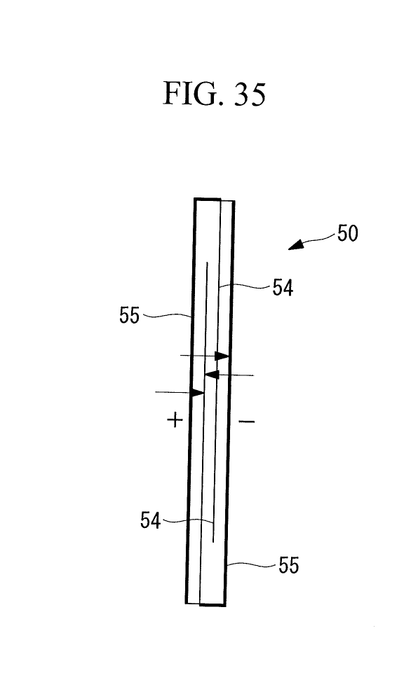

Next, an ultrasonic surgical apparatus according to a fourth embodiment of the present invention will be described with reference to FIGS. 33 to 35.

A piezoelectric element 50 employed in this embodiment is a piezoelectric element having a laminated structure, that is, a laminated piezoelectric element. As shown in FIG. 34, internal electrodes (silver palladium) 54 are formed on the laminated piezoelectric element 50 by providing insulating portions on parts of the surfaces of individual piezoelectric sheets (piezoelectric-element members) 51, 52, and 53 having a thickness of several tens of micrometers. These sheets are laminated as shown in FIG. 34, followed by firing. Finally, external electrodes (silver) 55 are plated, as shown in FIG. 34.

With the ultrasonic surgical apparatus according to this embodiment, employing the laminated piezoelectric element as described above, by employing the laminated piezoelectric element, the drive voltage can be reduced by an amount corresponding to the reciprocal of the number of laminated sheets. Because a three-layered structure is employed in the laminated piezoelectric element in this embodiment, the drive voltage can be reduced to ⅓ as compared with the case in which a normal single-plate piezoelectric element is employed.

In this embodiment, the same control as that in the third embodiment described above is made possible by providing vibration detection regions in portions of the internal electrodes 54, which makes it possible to achieve stable melting of fat.

In addition, although a laminated piezoelectric element having a three-layer structure is employed in this embodiment, a laminated piezoelectric element having an N-layer structure (N is an arbitrary integer) may be employed. In this case, the drive voltage can be set to 1/N.

As described above, although the embodiments of the present invention have been described in detail with reference to the drawings, specific configurations are not limited to these embodiments, and design alterations or the like within a range that does not depart from the spirit of the present invention are also encompassed. For example, the present invention is not limited to application in the individual embodiments and modifications described above, it may be employed in embodiments in which these embodiments and modifications are appropriately combined, and there is no particular limitation. In addition, in the individual embodiments above-described, the polygonal columnar elastic bodies 11, 31, and 61 having a substantially regular polygonal cross-section have been described as examples of the columnar member; however, a columnar member having a substantially circular cross-section may be employed instead of a columnar member having a substantially regular polygonal cross-section, so long as the piezoelectric elements 12 can be secured in close contact with side surfaces thereof.

The following aspect of the invention are derived from the above embodiments.

An aspect of the present invention is an ultrasonic vibration apparatus including a columnar member that is formed of an elastic body and that has a substantially circular cross-section or a substantially regular polygonal cross-section; plate-like piezoelectric elements that are secured on mutually opposing side surfaces of the columnar member and that are polarized in a plate-thickness direction; a rod-like member that is secured to an end of the columnar member and that has a smaller diameter than the columnar member; and a voltage applying portion that causes the rod-like member to ultrasonically vibrate by generating a vertical vibration which expands/contracts the columnar member in the longitudinal direction by applying an AC voltage to the piezoelectric elements in the plate-thickness direction.

With this aspect, when the voltage applying portion applies the AC voltage to the piezoelectric elements in the plate-thickness direction, the piezoelectric elements expand/contract in a direction orthogonal to the polarization direction thereof, that is, a direction orthogonal to the plate-thickness direction, which thereby generates vertical vibrations in the columnar member formed of the elastic body. Then, vibrations in the direction parallel to an axial line are transmitted to the rod-like member due to the vertical vibrations of the columnar member, causing the rod-like member to ultrasonically vibrate in the axial direction. Therefore, by inserting such a rod-like member into a body cavity, such as a pericardial cavity or the like, and by causing the rod-like member to ultrasonically vibrate in a state in which the tip of the rod-like member is in contact with fat adhered to an internal wall of the body cavity, the fat can be melted (emulsified) by the friction between the tip of the rod-like member and the fat.

In this case, by constructing the transducer so that the plate-like piezoelectric elements are secured on the side surfaces of the columnar member having a substantially circular or a substantially regular polygonal cross-section, it is possible to ensure substantially uniform rigidity in all radial directions of the transducer while achieving a reduction in the diameter of the columnar member and a size reduction of the piezoelectric elements. Accordingly, for example, regardless of the angle and orientation with which the tip of the rod-like member is brought into contact with the fat, the fat can be melted by uniformly generating friction.

In the above-described aspect, the columnar member may be a substantially polygonal columnar member.

With such a configuration, the flat-plate-like piezoelectric elements can be secured to the individual side surfaces of the columnar member. Therefore, for example, if the columnar member is a rectangular columnar member, the piezoelectric elements are secured to the four side surfaces thereof, and the piezoelectric elements are caused to uniformly expand/contract, thereby efficiently generating vertical vibrations in the columnar member, which makes it possible to enhance vibrations in the axial direction transmitted to the rod-like member. Note that, if a pair of piezoelectric elements is disposed on one set of two mutually opposing side surfaces of the columnar member, the size of the apparatus can be further reduced while efficiently achieving vertical vibrations in the columnar member.

In addition, in the above-described aspect, the columnar member may have a substantially circular-cone shape or a substantially geometrical-pyramid shape in which the cross-sectional area thereof decreases toward the end to which the rod-like member is secured.

With such a configuration, it is possible to make the mechanical impedances of the rod-like member and the columnar member similar at the securing position therebetween by making the cross-sectional area of the columnar member at the end thereof closer to the cross-sectional area of the rod-like member. Therefore, good mechanical impedance matching can be achieved between the columnar member and the rod-like member, and the vibrational energy of the columnar member can be transmitted efficiently to the rod-like member.

In addition, by forming the columnar member in a substantially circular-cone shape or a substantially geometrical-pyramid shape, the cross-sectional area can be increased at the basal end opposite from the end to which the rod-like member is secured. Accordingly, the surface areas can be increased in the piezoelectric elements secured to the basal end of the side surfaces of the columnar member, and the vibrational energy generated at the columnar member can be increased. In addition, by making the end of the columnar member smaller, the usability of the apparatus can be improved by enhancing the ease of insertion into a body cavity and so forth.

In addition, in the above-described aspect, a pair of the piezoelectric elements disposed facing each other, with the columnar member placed therebetween, may be secured to the columnar member so that orientations of the polarizations thereof are directed in the same direction with respect to each other.

With such a configuration, the pair of piezoelectric elements can be expanded/contracted with the same phases as each other by connecting the pair of piezoelectric elements facing each other by means of leads of different phases, which makes it possible to generate vertical vibrations in the columnar member. Therefore, a lead to be connected to ground is not required, which makes it possible to reduce the number of wires.

In addition, in the above-described aspect, a pair of piezoelectric elements disposed facing each other, with the columnar member placed therebetween, may be secured to the columnar member so that orientations of the polarizations thereof are directed in opposite directions with respect to each other.

With such a configuration, the pair of piezoelectric elements can be expanded/contracted with the same phases as each other by connecting the pair of piezoelectric elements facing each other by means of leads of the same phase, which makes it possible to generate vertical vibrations in the columnar member.

In addition, the above-described aspect may be provided with a case that accommodates the columnar member; and a holding member that is provided between the case and the columnar member and that holds the columnar member at a node of the vertical vibration.

With such a configuration, the columnar member can be held in the case via the holding member. By holding the columnar member at the node of bending vibrations in this way, it is possible to prevent vibrational energy generated at the columnar member from escaping outside the case. Accordingly, ultrasonic vibrations can efficiently be generated at the rod-like member.

In addition, in the above-described aspect, the columnar member and the rod-like member may have suction paths through which tissue can be sucked.

With such a configuration, tissue melted by ultrasonic vibrations of the rod-like member (for example, emulsified fat components) can be ejected outside via the suction path.

In addition, in the above-described aspect, the columnar member and the rod-like member may be provided with liquid-supplying paths through which liquid can be supplied.

With such a configuration, liquid, such as saline solution or the like, can be supplied into a body cavity via the liquid-supplying path, which makes it possible to facilitate the propagation of ultrasonic vibrations of the rod-like member to a biological subject by means of the liquid. Accordingly, it is possible to enhance the efficiency in emulsifying fat.

In addition, the above-described aspect may be provided with a vibration-detecting electrode that detects a vibration in the columnar member; and a frequency control portion that changes the frequency of the AC voltage to be applied by the voltage applying portion so that an amplitude value of a vibration detected by the vibration-detecting electrode becomes equal to an amplitude value set in advance.

With such a configuration, when a load fluctuation occurs in the amplitude values of the vertical vibrations in the columnar member detected by the vibration-detecting electrode, the amplitude values of the vertical vibrations in the columnar member, that is, the amplitude values of the ultrasonic vibrations in the rod-like member, can be maintained constant by the operation of the frequency control portion.

In addition, in the above-described aspect, the piezoelectric element may be formed by laminating a plurality of piezoelectric-element members.

With such a configuration, as compared with the case where a single-layer piezoelectric element (single-plate piezoelectric element) having the same external dimensions is driven, the drive voltage can be reduced by an amount substantially corresponding to the reciprocal of the number of laminated layers of the piezoelectric element members. For example, when a laminated piezoelectric element having a three-layered structure is employed, the drive voltage can be reduced to ⅓ as compared with the case in which a single-plate piezoelectric element is employed.

### REFERENCE SIGNS LIST

1, 2, 3 ultrasonic surgical apparatus (ultrasonic vibration apparatus)
11, 31, 61 polygonal columnar elastic body (columnar member)
12 piezoelectric element
13 rod-like contactor (rod-like member)
15 case
16 rubber piece (holding member)
21 drive-pulse generating circuit (voltage applying portion)
27 frequency control circuit (frequency control portion)
35 through-hole (suction path)
36a liquid-supplying through-hole (liquid-supplying path)
36b suction through-hole (suction path)
42 vibration-detection electrode (vibration-detecting electrode)
51, 52, 53 piezoelectric sheet (piezoelectric-element member)

1. An ultrasonic vibration apparatus comprising:
a columnar member that is formed of an elastic body and that has a substantially circular cross-section or a substantially regular polygonal cross-section;
plate-like piezoelectric elements that are secured on mutually opposing side surfaces of the columnar member and that are polarized in a plate-thickness direction;
a rod-like member that is secured to an end of the columnar member and that has a smaller diameter than the columnar member; and
a voltage applying portion that causes the rod-like member to ultrasonically vibrate by generating a vertical vibration which expands/contracts the columnar member in the longitudinal direction by applying an AC voltage to the piezoelectric elements in the plate-thickness direction.

2. An ultrasonic vibration apparatus according to claim 1, wherein the columnar member is a substantially polygonal columnar member.

3. An ultrasonic vibration apparatus according to claim 1, wherein the columnar member has a substantially circular-cone shape or a substantially geometrical-pyramid shape in which the cross-sectional area thereof decreases toward the end to which the rod-like member is secured.

4. An ultrasonic vibration apparatus according to claim 1, wherein a pair of the piezoelectric elements disposed facing each other, with the columnar member placed therebetween, are secured to the columnar member so that orientations of the polarizations thereof are directed in the same direction with respect to each other.

5. An ultrasonic vibration apparatus according to claim 1, wherein a pair of piezoelectric elements disposed facing each other, with the columnar member placed therebetween, are secured to the columnar member so that orientations of the polarizations thereof are directed in opposite directions with respect to each other.

6. Au ultrasonic vibration apparatus according to claim 1, further comprising:
a case that accommodates the columnar member; and
a holding member that is provided between the case and the columnar member and that holds the columnar member at a node of the vertical vibration.

7. An ultrasonic vibration apparatus according to claim 1, wherein the columnar member and the rod-like member have suction paths through which tissue can be sucked.

8. An ultrasonic vibration apparatus according to claim 7, wherein the columnar member and the rod-like member are provided with liquid-supplying paths through which liquid can be supplied.

9. An ultrasonic vibration apparatus according to claim 1, further comprising:
a vibration-detecting electrode that detects a vibration in the columnar member; and
a frequency control portion that changes the frequency of the AC voltage to be applied by the voltage applying portion so that an amplitude value of a vibration detected by the vibration-detecting electrode becomes equal to an amplitude value set in advance.

10. An ultrasonic vibration apparatus according to claim 1, wherein the piezoelectric element is formed by laminating a plurality of piezoelectric-element members.
